(19) United States
(12) Patent Application Publication
(10) Pub. No.: US 2026/0112425 A1
(43) Pub. Date: Apr. 23, 2026

(54) MEMORY DEVICE, STORAGE DEVICE, AND OPERATING METHOD OF STORAGE DEVICE

(71) Applicant: SK hynix Inc., Gyeonggi-do (KR)

(72) Inventor: Byoung Sung YOU, Gyeonggi-do (KR)

(21) Appl. No.: 19/045,565

(22) Filed: Feb. 5, 2025

(30) Foreign Application Priority Data
Oct. 21, 2024 (KR) 10-2024-0144338

(51) Int. Cl. G11C 16/34; G11C 16/04; G11C 16/16

(52) U.S. Cl. CPC G11C 16/344; G11C 16/0483; G11C 16/16

(57) ABSTRACT

A memory device includes a plurality of blocks, each block including memory cells, and a control circuit configured to enable a blind erase option and perform a blind erase operation on a target block among the plurality of blocks. The control circuit, during the blind erase operation, is configured to perform an erase pulse applying operation on the target block without performing an erase verifying operation on the target block.

### CROSS-REFERENCES TO RELATED APPLICATION

The present application claims priority under 35 U.S.C. § 119(a) to Korean application number 10-2024-0144338, filed on Oct. 21, 2024, which is incorporated herein by reference in its entirety.

### BACKGROUND

### 1. Technical Field

Embodiments of the present disclosure relate to a memory device and a storage device including the memory device.

### 2. Related Art

A storage device may store data provided from an external device, in response to a write request from the external device. Furthermore, the storage device may provide the external device with data stored therein, in response to a read request from the external device. The external device, which is an electronic device capable of processing data, may include a computer, a digital camera, or a mobile phone. The storage device may be embedded in the external device and operate, or may operate by being manufactured in a detachable form and being coupled to the external device. The storage device may include a memory device for storing data.

A memory device may require an erase operation to erase data and secure a space for storing new data. For example, because a non-volatile memory device such as a flash memory cannot overwrite data, original data must be erased before new data can be written. The time it takes to perform the erase operation has a significant impact on the operating performance of a storage device, and frequent erase operations may also affect the lifespan of the memory device. When the memory device efficiently performs the erase operation, the operating performance of the storage device may be maximized.

### SUMMARY

A memory device according to an embodiment of the present disclosure may include a plurality of blocks, each block including memory cells; and a control circuit configured to enable a blind erase option and perform a blind erase operation on a target block among the plurality of blocks. The control circuit, during the blind erase operation, may perform an erase pulse applying operation on the target block without performing an erase verifying operation on the target block.

A storage device according to an embodiment of the present disclosure may include a memory device including a plurality of blocks, each block including memory cells; and a controller configured to control the memory device to perform a blind erase operation on a target block among the plurality of blocks, and a fast erase operation on the target block in response to a determination that a new open block is required. During the blind erase operation, the memory device may perform an erase pulse applying operation on the target block without performing an erase verifying operation on the target block.

An operating method of a storage device including a memory device and a controller, according to an embodiment of the present disclosure may include controlling, by the controller, the memory device to perform a blind erase operation on a target block; and controlling, by the controller, the memory device to perform a fast erase operation on the target block in response to a determination that a new open block is required.

### BRIEF DESCRIPTION OF THE DRAWINGS

FIG. 1 is a block diagram illustrating a storage device, according to an embodiment of the present disclosure.

FIG. 2 is a circuit diagram illustrating a memory block, according to an embodiment of the present disclosure.

FIG. 3 is a diagram illustrating a process in which a storage device designates and uses a new open block through a normal erase operation, according to an embodiment of the present disclosure.

FIG. 4 is a diagram illustrating a process in which a storage device designates and uses a new open block through a blind erase operation and a fast erase operation, according to an embodiment of the present disclosure.

FIGS. 5A to 5C are diagrams illustrating command sets transmitted from a controller to a memory device, according to an embodiment of the present disclosure.

FIG. 6 is a flowchart illustrating an operation of a controller, according to an embodiment of the present disclosure.

FIG. 7 is a flowchart illustrating an operation of a controller, according to an embodiment of the present disclosure.

FIG. 8 is a flowchart illustrating an operation of a controller, according to an embodiment of the present disclosure.

FIG. 9 is a flowchart illustrating an operation of a controller, according to an embodiment of the present disclosure.

FIG. 10 is a flowchart illustrating an operation of a memory device, according to an embodiment of the present disclosure.

### DETAILED DESCRIPTION

Hereinafter, embodiments of the present disclosure will be described in more detail with reference to the accompanying drawings.

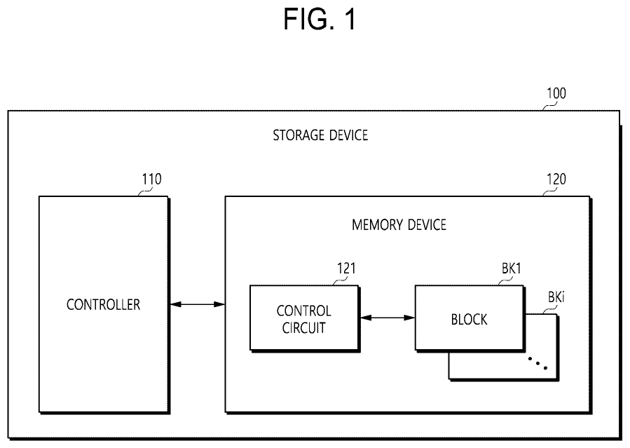

FIG. 1 is a block diagram illustrating a storage device 100, according to an embodiment of the present disclosure.

The storage device 100 may store data received from a host device (e.g., an external device) in response to a write request from the host device (not illustrated). In addition, the storage device 100 may transmit data stored therein to the host device in response to a read request from the host device.

The storage device 100 may include a controller 110 and a memory device 120.

The controller 110 may control an operation of the storage device 100. The controller 110 may control the memory device 120 according to a request from the host device. For example, the controller 110 may store data transmitted from the host device in the memory device 120 according to the write request from the host device. In addition, the controller 110 may read data from the memory device 120 and transmit the data to the host device, according to the read request from the host device.

In addition, the controller 110 may control the memory device 120 to perform a management operation required internally, independently of the host device, that is, even without receiving a request from the host device. The management operation may include a wear-leveling operation, a deduplication operation, and a garbage collection operation. Depending on an embodiment, the controller 110 may also perform the management operations according to the request from the host device. The controller 110 may perform the management operation in the background or in the foreground.

An open block may be a block, which is designated for a memory device 120 to perform a program operation, among blocks BK1 to BKi of the memory device 120. When there is no more empty space in an open block designated currently, the controller 110 may designate an empty block as a new open block.

The controller 110 may control the memory device 120 to perform a normal erase operation to generate an empty block. The normal erase operation may be performed by repeating an erase pulse applying operation and an erase verifying operation one or more times. The normal erase operation may further include an additional erase pulse applying operation and an additional erase verifying operation, depending on a result of performing a previous erase verifying operation. In the normal erase operation, the erase pulse applying operation and the erase verifying operation may be linked or paired. The erase pulse applying operation may be an operation to erase data stored in memory cells by applying an erase pulse having a high voltage level to a channel of the memory cells. The erase verifying operation may be an operation to verify whether data stored in memory cells has been erased by reading the data stored in the memory cells.

The memory device 120 may perform a read operation, a program operation, an erase operation, etc. under the control of the controller 110. The memory device 120 may include a control circuit 121 and a plurality of blocks BK1 to BKi. The control circuit 121 may control overall operations of the memory device 120 under the control of the controller 110. Each of the blocks BK1 to BKi may be a unit in which the memory device 120 performs the erase operation under the control of the controller 110. Each of the blocks BK1 to BKi may include a plurality of memory cells in which data are stored.

According to an embodiment, the memory device 120 may include one or more planes. Each of the planes may be a group of the blocks BK1 to BKi that share bit lines. Each of the blocks BK1 to BKi may be composed of one or more memory blocks included in each of one or more planes.

The controller 110 may control the memory device 120 to perform a blind erase operation on a target block among the plurality of blocks BK1 to BKi, and control the memory device 120 to perform a fast erase operation on the target block in response to a determination that a new open block is required.

During the blind erase operation, one erase pulse may be applied to the target block. During the blind erase operation, the control circuit 121 may not perform the erase verifying operation on the target block after performing the erase pulse applying operation on the target block. The blind erase operation may not include the erase verifying operation of verifying whether the target block is completely erased.

The fast erase operation may include a pre-erase verifying operation that is performed first without the erase pulse applying operation. During the fast erase operation, the control circuit 121 may not perform the erase pulse applying operation on the target block before performing the pre-erase verifying operation on the target block. The control circuit 121 may perform the normal erase operation on the target block in response to a determination that a result of the pre-erase verifying operation is “fail”.

In an embodiment, the controller 110 may control the memory device 120 to perform the blind erase operation, in response to a determination that the memory device 120 is in an idle state. In an embodiment, the controller 110 may control the memory device 120 to perform the blind erase operation, in response to a determination that there are no pending operations for the memory device 120.

In an embodiment, the controller 110 may control the memory device 120 to perform the blind erase operation by enabling a blind erase option in the memory device 120 and then transmitting an erase command set to the memory device 120. The controller 110 may sequentially transmit a settings command set for enabling the blind erase option and the erase command set to the memory device 120. The erase command set may be transmitted subsequent to the setting command set for enabling the blind erase option, thereby instructing the memory device 120 to perform the blind erase operation.

In an embodiment, the controller 110 may control the memory device 120 to perform the fast erase operation by enabling a pre-erase verifying option in the memory device 120 and then transmitting an erase command set to the memory device 120. The controller 110 may sequentially transmit a setting command set for enabling the pre-erase verifying option and the erase command set to the memory device 120. The erase command set may be transmitted subsequent to the setting command set for enabling the pre-erase verifying option, thereby instructing the memory device 120 to perform the fast erase operation.

In an embodiment, the controller 110 may control the memory device 120 to perform the normal erase operation by transmitting only an erase command set without a setting command set to the memory device 120.

In an embodiment, the controller 110 may select a target block from an invalid block pool for the blind erase operation. The invalid block pool may be composed of blocks containing only invalid data. The controller 110 may register the target block on which the blind erase operation has been performed in a free block pool. The free block pool may be composed of blocks on which the blind erase operation has been performed. The target block may be registered in the free block pool after the blind erase operation has been performed, regardless of whether the target block has been completely erased. The controller 110 may select a target block from the free block pool in response to a determination that a new open block is needed.

In an embodiment, the controller 110 may determine whether a new open block is needed, in response to the write request received from the host device. In response to a determination that the new open block is needed, the controller 110 may control the memory device 120 to perform the fast erase operation on the target block. The controller 110 may designate the target block as the new open block after the fast erase operation is performed, and control the memory device 120 to perform the program operation on the target block.

The control circuit 121 may enable the blind erase option and perform the blind erase operation on the target block, under the control of the controller 110. The control circuit 121 may enable the blind erase option in response to the setting command set for enabling the blind erase option, and perform the blind erase operation in response to the erase command set that is continuous to the setting command set.

The control circuit 121 may enable the pre-erase verifying option and perform the fast erase operation on the target block, under the control of the controller 110. The control circuit 121 may enable the pre-erase verifying option in response to the setting command set for enabling the pre-erase verifying option, and perform the fast erase operation in response to the erase command set that is continuous to the setting command set.

Although not illustrated, the control circuit 121 may include a decoder for selecting a target block among the plurality of blocks BK1 to BKi, a voltage generation circuit for supplying voltages required for the erase pulse applying operation, the erase verifying operation and the program operation to the target block, and an option setting circuit for setting enable/disable of the blind erase option and the pre-erase verifying option.

In an embodiment, the storage device 100 may include a personal computer memory card international association (PCMCIA) card, a smart media card, a memory stick, various multi-media cards such as MMC, eMMC, RS-MMC and MMC-micro, a secure digital (SD) card such as SD, Mini-SD and Micro-SD, a universal flash storage (UFS), or a solid state drive (SSD).

In an embodiment, the memory device 120 may include a NAND flash memory, a 3D NAND flash memory, a NOR flash memory, a resistive random access memory (RRAM), a phase-change memory (PRAM), a magnetoresistive random access memory (MRAM), a ferroelectric random access memory (FRAM), and a spin transfer torque random access memory (STT-RAM).

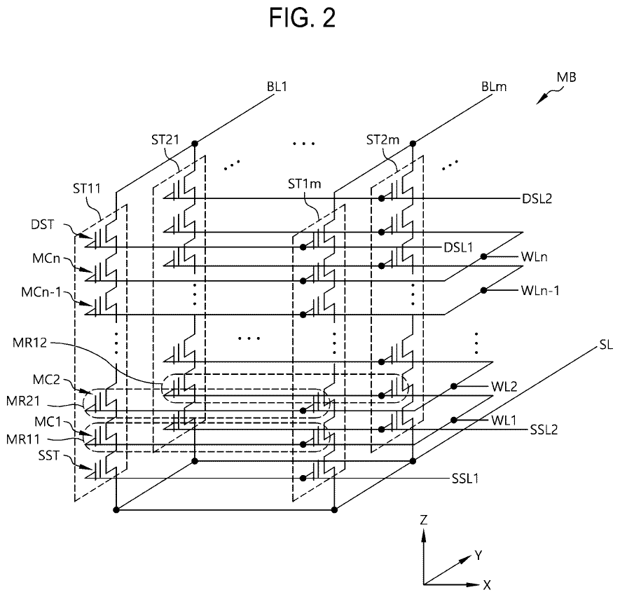

FIG. 2 is a circuit diagram illustrating a memory block MB, according to an embodiment of the present disclosure. Each of the blocks BK1 to BKi of FIG. 1 may include one or more memory blocks configured similarly to the memory block MB of FIG. 2.

Referring to FIG. 2, the memory block MB may be coupled to the control circuit 121 through selection lines DSL1, DSL2, SL1 and SL2, word lines WL1 to WLn, bit lines BL1 to BLm, and a source line SL.

The memory block MB may include strings ST11 to ST1m and ST21 to ST2m. Each of the strings ST11 to ST1m and ST21 to ST2m may extend in a vertical direction, i.e., a Z direction. In the memory block MB, “m” strings may be arranged in a row direction, i.e., an X direction. Although FIG. 2 illustrates that two strings are arranged in a column direction, i.e., a Y direction, this is for convenience in description, and three or more strings may be arranged in the column direction, i.e., the Y direction.

The strings ST11 to ST1m and ST21 to ST2m may be configured in the same manner. For example, the string ST11 may include a source selection transistor ST, memory cells MC1 to MCn, and a drain selection transistor DST, which are coupled in series to one another between the source line SL and the bit line BL1. A source of the source selection transistor ST may be coupled to the source line SL, and a drain of the drain selection transistor DST may be coupled to the bit line BL1. The memory cells MC1 to MCn may be coupled in series to one another between the source selection transistor ST and the drain selection transistor DST. In an embodiment, a plurality of source selection transistors may be coupled in series to one another between the source line SL and the memory cell MC1. In an embodiment, a plurality of drain selection transistors may be coupled in series to one another between the bit line BL1 and the memory cell MCn.

Source selection transistors at the same position in the vertical direction may be configured in the following manner. Specifically, gates of source selection transistors of strings arranged in the same row may be coupled to the same source selection line. For example, gates of source selection transistors of the strings ST11 to ST1m arranged in a first row may be coupled to the source selection line SL1. For example, gates of source selection transistors of the strings ST21 to ST2m arranged in a second row may be coupled to the source selection line SL2.

In an embodiment, source selection transistors of strings arranged in two or more rows may be coupled in common to one source selection line. For example, the source selection transistors of the strings ST11 to ST1m and ST21 to ST2m arranged in the first and second rows may be coupled in common to one source selection line, and source selection transistors of strings arranged in third and fourth rows may be coupled in common to one source selection line.

Drain selection transistors at the same position in the vertical direction may be configured in the following manner. Specifically, gates of drain selection transistors of strings arranged in the same row may be coupled to the same drain selection line. For example, gates of drain selection transistors of the strings ST11 to ST1m arranged in the first row may be coupled to the drain selection line DSL1. For example, gates of drain selection transistors of the strings ST21 to ST2m arranged in the second row may be coupled to the drain selection line DSL2.

Strings arranged in the same column may be coupled to the same bit line. For example, the strings ST11 and ST21 arranged in a first column may be coupled to the bit line BL1. For example, the strings ST1m and ST2m arranged in an m^{th} column may be coupled to the bit line BLm.

Gates of memory cells at the same position in the vertical direction may be coupled to the same word line. For example, memory cells at the same position in the vertical direction as the memory cell MC1 in the strings ST11˜ST1m and ST21˜ST2m may be coupled to the word line WL1.

Among the memory cells, memory cells coupled to the same word line in the same row may constitute one memory region. For example, memory cells coupled to the word line WL1 in the first row may constitute one memory region MR11. For example, memory cells coupled to the word line WL1 in the second row may constitute one memory region MR12. For example, memory cells coupled to the word line WL2 in the first row may constitute one memory region MR21. Depending on a quantity of rows, each word line may be coupled to a plurality of memory regions. The memory cells constituting one memory region may be accessed simultaneously.

In an embodiment, the memory block MB may be further coupled to one or more dummy word lines other than the word lines WL1 to WLn. In this case, the memory block MB may further include dummy memory cells coupled to the dummy word lines.

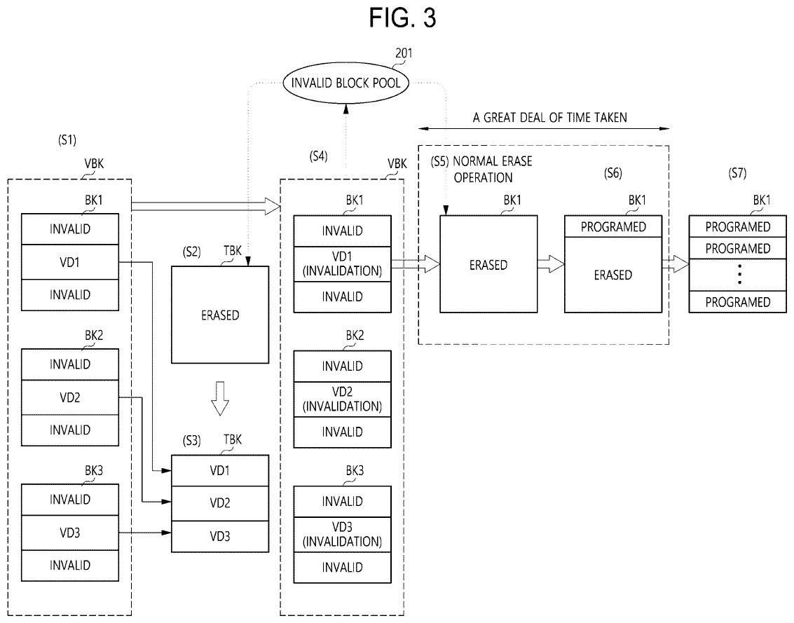

FIG. 3 is a diagram illustrating a process in which the storage device 100 designates and uses a new open block through the normal erase operation, according to an embodiment of the present disclosure.

Referring to FIG. 3, in operation S1, the controller 110 may select blocks BK1 to BK3 as victim blocks VBK. It may be described as an example that a quantity of victim blocks VBK is 3. Each of valid data VD1, VD2 and VD3 may be stored in a different one of the victim blocks VBK. Data other than the valid data VD1, VD2 and VD3 in the victim blocks VBK may be invalid.

In operation S2, the controller 110 may select a target block TBK for a garbage collection operation. In an embodiment, the controller 110 may select the target block TBK for the garbage collection operation from an invalid block pool 201 composed of blocks containing only invalid data, and control the memory device 120 to perform the normal erase operation on the target block TBK. In an embodiment, the controller 110 may select an empty block, which has already been erased, as the target block TBK.

In operation S3, the controller 110 may store the valid data VD1, VD2 and VD3, which are stored in the victim blocks VBK, in the target block TBK.

In operation S4, the controller 110 may invalidate the valid data VD1, VD2 and VD3 stored in the victim blocks VBK. In an embodiment, the controller 110 may invalidate the valid data VD1, VD2 and VD3 and then register the victim blocks VBK in the invalid block pool 201.

In operation S5, the controller 110 may select the block BK1 from the invalid block pool 201 and control the memory device 120 to perform the normal erase operation on the block BK1.

In operation S6, the controller 110 may designate the block BK1 as a new open block and control the memory device 120 to perform a first program operation on the empty block BK1.

In operation S7, the controller 110 may continue to use the block BK1 as the open block until there is no empty space in the block BK1. The controller 110 may designate a new open block instead of the block BK1 when all memory regions of the block BK1 are programmed.

According to the process described with reference to FIG. 3, the normal erase operation for the block BK1 in operation S5 and the first program operation for the block BK1 in operation S6 may be linked or paired. When a new open block is selected from the invalid block pool 201, the normal erase operation for the block BK1 may not be skipped before the first program operation for the block BK1 is performed. Accordingly, a great deal of time is taken for the operations S5 and S6 until the first program operation for the block BK1 is completely performed, which may cause a degradation in performance of the storage device 100.

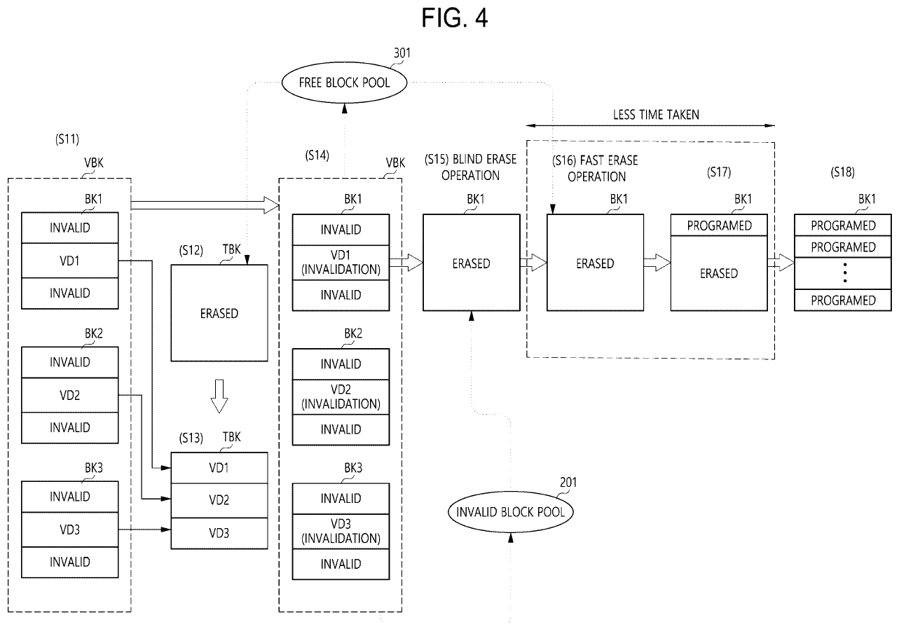

FIG. 4 is a diagram illustrating a process in which the storage device 100 designates and uses a new open block through the blind erase operation and the fast erase operation, according to an embodiment of the present disclosure.

Referring to FIG. 4, in operation S11, the controller 110 may select blocks BK1 to BK3 as victim blocks VBK.

In operation S12, the controller 110 may select a target block TBK for a garbage collection operation. In an embodiment, the controller 110 may select the target block TBK from a free block pool 301 composed of blocks on which the blind erase operation has been performed. When the target block TBK is selected from the free block pool 301, the controller 110 may control the memory device 120 to perform the fast erase operation on the target block TBK. In an embodiment, the controller 110 may select an empty block, which has already been erased, as the target block TBK.

In operation S13, the controller 110 may store valid data VD1, VD2 and VD3, which are stored in the victim blocks VBK, in the target block TBK.

In operation S14, the controller 110 may invalidate the valid data VD1, VD2 and VD3 stored in the victim blocks VBK. After invalidating the valid data VD1, VD2 and VD3, the controller 110 may register the victim blocks VBK in an invalid block pool 201.

In operation S15, the controller 110 may select the block BK1 from the invalid block pool 201 and control the memory device 120 to perform the blind erase operation on the block BK1. After the blind erase operation is performed, the block BK1 may be removed from the invalid block pool 201 and registered in the free block pool 301.

After the operation S15 is performed, the controller 110 may perform operations S16 and S17 in response to a determination that a new open block is needed for a program operation.

In operation S16, the controller 110 may select the block BK1 from the free block pool 301 and control the memory device 120 to perform the fast erase operation on the block BK1.

In operation S17, the controller 110 may designate the block BK1 as a new open block and control the memory device 120 to perform a first program operation on the block BK1.

In operation S18, the controller 110 may continue to use the block BK1 as the open block until there is no empty space in the block BK1. The controller 110 may designate a new open block instead of the block BK1 when all memory regions of the block BK1 are programmed.

According to the process described with reference to FIG. 4, the fast erase operation for the block BK1 in operation S16 and the first program operation for the block BK in operation S17 may be linked or paired. However, because the blind erase operation for the block BK1 has been performed in advance in operation S15, the fast erase operation may be performed quickly by starting from the pre-erase verifying operation without the erase pulse applying operation. Accordingly, less time is taken for the operations S16 and S17 until the first program operation for the block BK1 is completely performed, and thus performance of the storage device 100 may be improved.

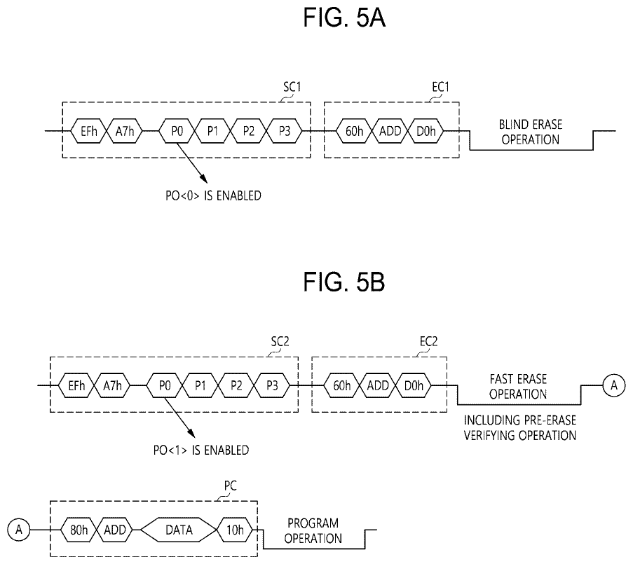

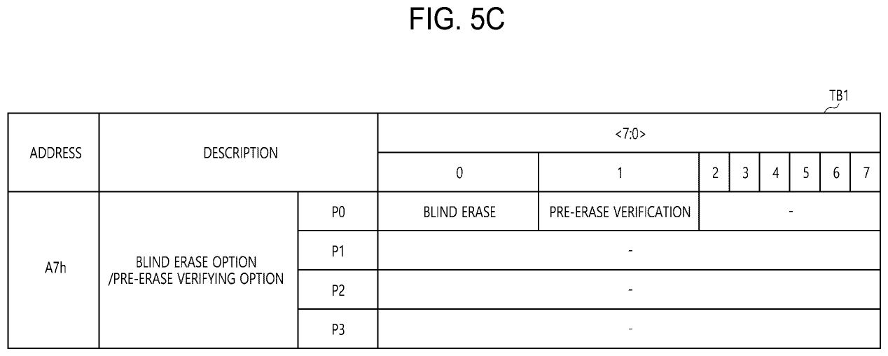

FIGS. 5A to 5C are diagrams illustrating command sets transmitted from the controller 110 to the memory device 120, according to an embodiment of the present disclosure.

Referring to FIG. 5A, a setting command set SC1 may be for enabling a blind erase option in the memory device 120. The setting command set SC1 may include a setting command EFh, an address A7h, and a first setting value P0 to a fourth setting value P3. The setting command EFh may be a command for setting an option, function or mode of the memory device 120. The address A7h may represent that an option to be set is the blind erase option or a pre-erase verifying option. The first setting value P0 to the fourth setting value P3 may represent whether to enable or disable the blind erase option or the pre-erase verifying option.

Referring to FIG. 5C, a table TB1 illustrates the usage of the first setting value P0 to the fourth setting value P3 for the address A7h of the setting command EFh. A zeroth bit of the first setting value P0 (i.e., P0<0>) may be for enabling or disabling the blind erase option. A first bit of the first setting value P0 (i.e., P0<1>) may be for enabling or disabling the pre-erase verifying option.

Referring back to FIG. 5A, the setting command set SC1 for enabling the blind erase option may be in a state where the zeroth bit of the first setting value P0 (i.e., P0<0>) is enabled and in a state where the first bit of the first setting value P0 (i.e., P0<1>) is disabled. The memory device 120 may enable the blind erase option in response to the setting command set SC1.

Subsequent to the setting command set SC1 for enabling the blind erase option, an erase command set EC1 may be transmitted to the memory device 120. The erase command set EC1 may include an erase command 60h, an address ADD, and a confirmation command D0h. The erase command 60h may instruct the memory device 120 to perform the blind erase operation when the blind erase option is enabled. The address ADD may indicate a target block on which the blind erase operation is to be performed when the blind erase option is enabled. The confirmation command D0h may confirm that the erase command set EC1 has been normally transmitted. The memory device 120 may perform the blind erase operation in response to the erase command set EC1 when the blind erase option is enabled.

The controller 110 may repeatedly perform the blind erase operation on a plurality of target blocks by repeatedly transmitting the setting command set SC1 and the erase command set EC1 to the memory device 120 while conditions for performing the blind erase operation are satisfied.

Referring to FIG. 5B, a setting command set SC2 may be for enabling a pre-erase verifying option in the memory device 120. The setting command set SC2 may include a setting command EFh, an address A7h, and a first setting value P0 to a fourth setting value P3. The setting command set SC2 for enabling the pre-erase verifying option may be in a state where a zeroth bit of the first setting value P0 (i.e., P0<0>) is disabled and in a state where a first bit of the first setting value P0 (i.e., P0<1>) is enabled. The memory device 120 may enable the pre-erase verifying option in response to the setting command set SC2.

Subsequent to the setting command set SC2 for enabling the pre-erase verifying option, an erase command set EC2 may be transmitted to the memory device 120. The erase command set EC2 may include an erase command 60h, an address ADD, and a confirmation command D0h. The erase command 60h may instruct the memory device 120 to perform the fast erase operation when the pre-erase verifying option is enabled. The address ADD may indicate a target block on which the fast erase operation is to be performed when the pre-erase verifying option is enabled. The confirmation command D0h may confirm that the erase command set EC2 has been normally transmitted. The memory device 120 may perform the fast erase operation in response to the erase command set EC2 when the pre-erase verifying option is enabled. The fast erase operation may be performed starting from the pre-erase verifying operation without the erase pulse applying operation.

When a result of performing the fast erase operation is “pass”, a program command set PC may be transmitted to the memory device 120. The program command set PC may include a program command 80h, an address ADD, data, and a confirmation command 10h. The program command 80h may be a command of instructing a program operation. The address ADD may indicate a page on which the program operation is to be performed in an open block. The data may be data on which the program operation is to be performed. The confirmation command 10h may be a command of confirming that the program command set PC has been normally transmitted. The memory device 120 may perform the program operation in response to the program command set PC.

An erase command set for instructing a normal erase operation may have the same configuration as the erase command set EC1 for instructing the blind erase operation and the erase command set EC2 for instructing the fast erase operation. The memory device 120 may determine whether the erase command set instructs the blind erase operation, the pre-erase verifying operation or the normal erase operation, depending on whether the blind erase option and the pre-erase verifying option are enabled.

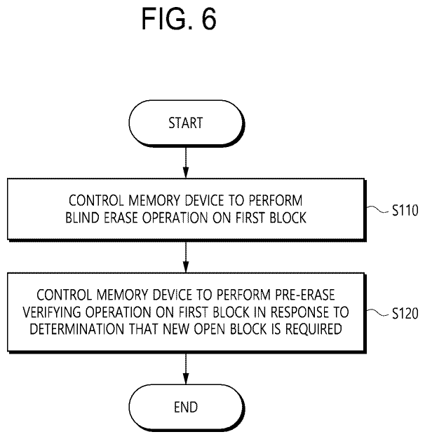

FIG. 6 is a flowchart illustrating an operation of the controller 110, according to an embodiment of the present disclosure.

Referring to FIG. 6, in operation S110, the controller 110 may control the memory device 120 to perform the blind erase operation on a target block. Specifically, the controller 110 may control the memory device 120 to perform the blind erase operation on the target block by enabling the blind erase option in the memory device 120 and transmitting the erase command set EC1 for the target block to the memory device 120.

In operation S120, the controller 110 may control the memory device 120 to perform the fast erase operation on the target block, in response to a determination that a new open block is required. Specifically, the controller 110 may control the memory device 120 to perform the fast erase operation on the target block by enabling the pre-erase verifying option in the memory device 120 and transmitting the erase command set EC2 for the target block to the memory device 120.

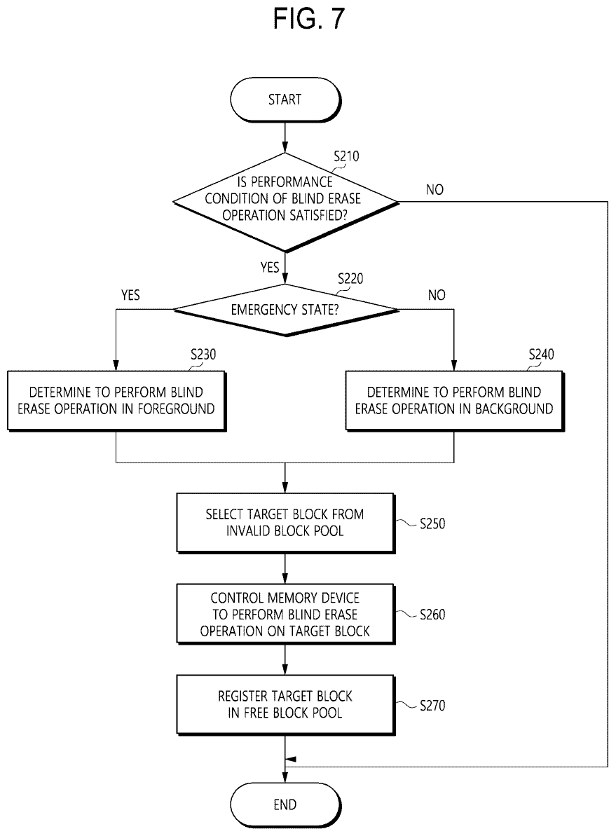

FIG. 7 is a flowchart illustrating an operation of the controller 110, according to an embodiment of the present disclosure.

Referring to FIG. 7, in operation S210, the controller 110 may determine whether a performance condition of the blind erase operation is satisfied. For example, the controller 110 may determine that the performance condition of the blind erase operation is satisfied when it is determined that the storage device 100 is in an idle state. For example, even while the controller 110 controls an operation for another memory device (not illustrated) included in the storage device 100, the controller 110 may determine that the performance condition of the blind erase operation is satisfied for the memory device 120 when it is determined that there is no pending operation for the memory device 120. When it is determined that the performance condition of the blind erase operation is satisfied, operation S220 may proceed. When it is determined that the performance condition of the blind erase operation is not satisfied, the operation may be terminated.

In the operation S220, the controller 110 may determine whether the memory device 120 is in an emergency state. The emergency state may be a state in which there is a shortage of empty blocks in the memory device 120. When it is determined that the memory device 120 is in the emergency state (i.e., “YES” in the operation S220), operation S230 may proceed. When it is determined that the memory device 120 is not in the emergency state (i.e., “NO” in the operation S220), operation S240 may proceed.

In operation S230, the controller 110 may determine to perform the blind erase operation in the foreground.

In operation S240, the controller 110 may determine to perform the blind erase operation in the background.

In operation S250, the controller 110 may select a target block on which the blind erase operation is to be performed from the invalid block pool 201.

In operation S260, the controller 110 may control the memory device 120 to perform the blind erase operation on the target block.

In operation S270, the controller 110 may register the target block on which the blind erase operation has been performed in the free block pool 301.

According to the embodiments of the present disclosure, the free block pool 301 may be secured through the blind erase operation, which makes it possible to improve performance of over-provisioning of the storage device 100.

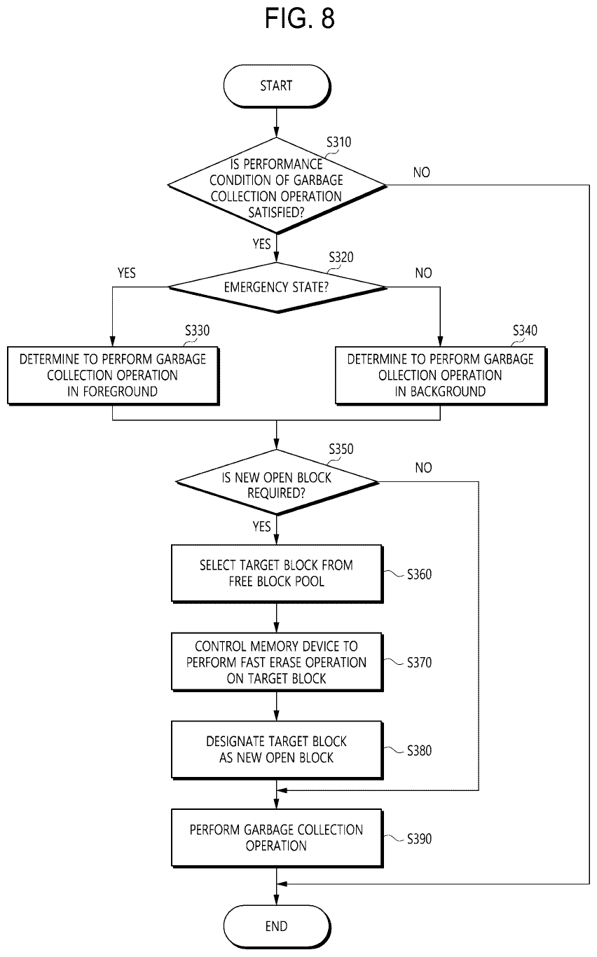

FIG. 8 is a flowchart illustrating an operation of the controller 110, according to an embodiment of the present disclosure.

Referring to FIG. 8, in operation S310, the controller 110 may determine whether a performance condition of the garbage collection operation is satisfied. For example, the controller 110 may determine that the performance condition of the garbage collection operation is satisfied when it is determined that the storage device 100 is in an idle state. For example, the controller 110 may determine that the performance condition of the garbage collection operation is satisfied when it is determined that a write request has been received from the host device. When it is determined that the performance condition of the garbage collection operation is satisfied (i.e., “YES” in the operation S310), operation S320 may proceed. When it is determined that the performance condition of the garbage collection operation is not satisfied (i.e., “NO” in the operation S310), the operation may be terminated.

In the operation S320, the controller 110 may determine whether the memory device 120 is in an emergency state. The emergency state may be a state in which there is a shortage of empty blocks in the memory device 120. When it is determined that the memory device 120 is in the emergency state (i.e., “YES” in the operation S320), operation S330 may proceed. When it is determined that the memory device 120 is not in the emergency state (i.e., “NO” in the operation S320), operation S340 may proceed.

In operation S330, the controller 110 may determine to perform the garbage collection operation in the foreground.

In operation S340, the controller 110 may determine to perform the garbage collection operation in the background.

In operation S350, the controller 110 may determine whether a new open block is required to move valid data from one or more victim blocks VBK of the garbage collection operation. When it is determined that the new open block is required, operation S360 may proceed. When it is determined that the new open block is not required, operation S390 may proceed.

In operation S360, the controller 110 may select a target block on which the fast erase operation is to be performed from the free block pool 301.

In operation S370, the controller 110 may control the memory device 120 to perform the fast erase operation on the target block.

In operation S380, the controller 110 may designate the target block as the new open block.

In operation S390, the controller 110 may perform the garbage collection operation on the open block. The garbage collection operation may include an operation of controlling the memory device 120 to store valid data stored in one or more victim blocks VBK in the open block, an operation of invalidating the valid data stored in one or more victim blocks VBK, and an operation of registering one or more victim blocks VBK in the invalid block pool 201.

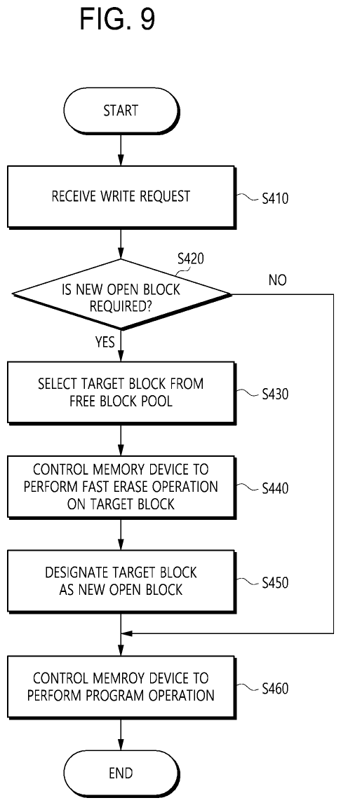

FIG. 9 is a flowchart illustrating an operation of the controller 110, according to an embodiment of the present disclosure.

Referring to FIG. 9, in operation S410, the controller 110 may receive a write request from the host device.

In operation S420, the controller 110 may determine whether a new open block is required to store data corresponding to the write request. When it is determined that the new open block is required (i.e., “YES” in the operation S420), operation S430 may proceed. When it is determined that the new open block is not required (i.e., “NO” in the operation S420), operation S460 may proceed.

In operation S430, the controller 110 may select a target block on which the fast erase operation is to be performed from the free block pool 301.

In operation S440, the controller 110 may control the memory device 120 to perform the fast erase operation on the target block.

In operation S450, the controller 110 may designate the target block as the new open block.

In the operation S460, the controller 110 may control the memory device 120 to perform the program operation on the open block. Data stored in the open block may include data corresponding to the write request.

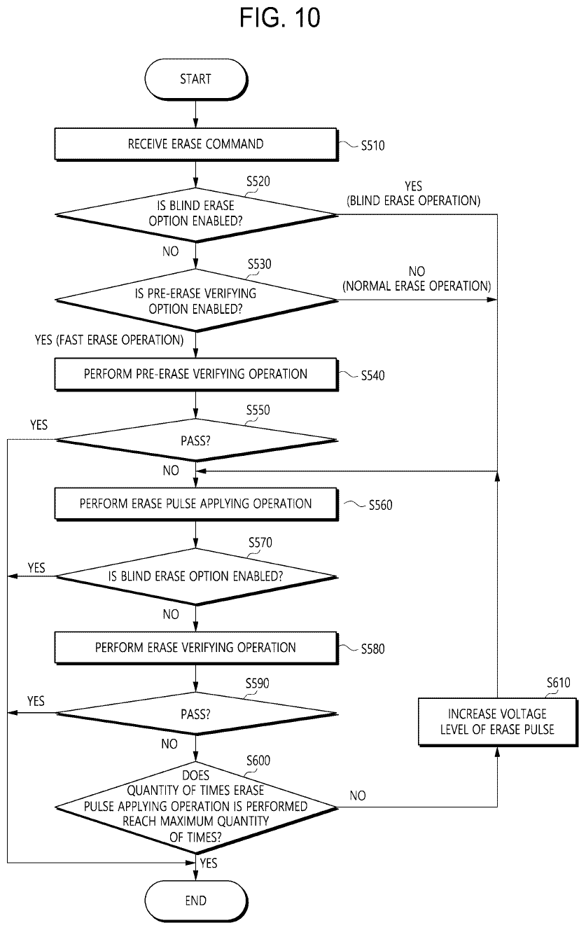

FIG. 10 is a flowchart illustrating an operation of the memory device 120, according to an embodiment of the present disclosure.

Referring to FIG. 10, in operation S510, the memory device 120 may receive an erase command for a target block.

In operation S520, the memory device 120 may determine whether a blind erase option is enabled. When it is determined that the blind erase option is enabled (i.e., “YES” in the operation S520), operation S560 may proceed so that a blind erase operation is performed. When it is determined that the blind erase option is disabled (i.e., “NO” in the operation S520), operation S530 may proceed.

In the operation S530, the memory device 120 may determine whether a pre-erase verifying option is enabled. When it is determined that the pre-erase verifying option is enabled (i.e., “YES” in the operation S530), operation S540 may proceed so that a fast erase operation is performed. When it is determined that the pre-erase verifying option is disabled (i.e., “YES” in the operation S530), the operation S560 may proceed so that a normal erase operation is performed.

In the operation S540, the memory device 120 may perform a pre-erase verifying operation on the target block.

In operation S550, the memory device 120 may determine whether a result of the pre-erase verifying operation is “pass”. When it is determined that the result of the pre-erase verifying operation is “pass” (i.e., “YES” in the operation S550), the operation may be terminated. When it is determined that the result of the pre-erase verifying operation is “fail” (i.e., “NO” in the operation S550), the operation S560 may proceed so that a normal erase operation is performed.

In the operation S560, the memory device 120 may perform an erase pulse applying operation on the target block.

In operation S570, the memory device 120 may determine whether the blind erase option is enabled. When it is determined that the blind erase option is enabled (i.e., “YES” in the operation S570), the operation may be terminated. When it is determined that the blind erase option is disabled (i.e., “NO” in the operation S570), operation S580 may proceed.

In the operation S580, the memory device 120 may perform an erase verifying operation on the target block.

In operation S590, the memory device 120 may determine whether a result of the erase verifying operation is “pass”. When it is determined that the result of the erase verifying operation is “pass” (i.e., “YES” in the operation S590), the operation may be terminated. When it is determined that the result of the erase verifying operation is “fail” (i.e., “NO” in the operation S590), operation S600 may proceed.

In the operation S600, the memory device 120 may determine whether a quantity of times the erase pulse applying operation is performed reaches a maximum quantity of times. When it is determined that the quantity of times the erase pulse applying operation is performed reaches the maximum quantity of times (i.e., “YES” in the operation S600), the operation may be terminated. When it is determined that the quantity of times the erase pulse applying operation is performed does not reach the maximum quantity of times (i.e., “NO” in the operation S600), operation S610 may proceed.

In the operation S610, the memory device 120 may increase a voltage level of an erase pulse. Subsequently, the erase pulse applying operation and the erase verifying operation may be repeatedly performed (i.e., the operation S560).

Although embodiments of the present disclosure have been described for illustrative purposes, those skilled in the art will appreciate that various modifications and changes are possible, without departing from the essential features of the present disclosure. Accordingly, the embodiments disclosed in the present disclosure are not intended to limit but illustrate the technical spirit of the present disclosure, and the scope of the technical spirit of the present disclosure is not limited by the embodiments. The protection scope of the present disclosure should be construed based on the following appended claims and it should be interpreted that all technical details included within the scope that are identical or equivalent to the claims belong to the scope of the present disclosure. Furthermore, the embodiments may be combined to form additional embodiments.

What is claimed is:

1. A memory device comprising:
a plurality of blocks, each block including memory cells; and
a control circuit configured to enable a blind erase option and perform a blind erase operation on a target block among the plurality of blocks,
wherein the control circuit, during the blind erase operation, is configured to perform an erase pulse applying operation on the target block without performing an erase verifying operation on the target block.

2. The memory device according to claim 1, wherein, during the blind erase operation, one erase pulse is applied to the target block.

3. The memory device according to claim 1,
wherein the control circuit is configured to enable the blind erase option in response to a setting command set for enabling the blind erase option, and perform the blind erase operation in response to an erase command set for the target block, and
wherein the erase command set is continuous to the setting command set.

4. The memory device according to claim 1, wherein the control circuit is configured to enable a pre-erase verifying option, and perform a fast erase operation on the target block.

5. The memory device according to claim 4,
wherein the control circuit is configured to enable the pre-erase verifying option in response to a setting command set for enabling the pre-erase verifying option, and perform the fast erase operation in response to an erase command set for the target block, and
wherein the erase command set is continuous to the setting command set.

6. The memory device according to claim 5, wherein, during the fast erase operation, the control circuit is configured not to perform an erase pulse applying operation on the target block before performing a pre-erase verifying operation on the target block.

7. The memory device according to claim 6, wherein, during the fast erase operation, the control circuit is configured to perform a normal erase operation on the target block in response to a determination that the pre-erase verifying operation fails.

8. A storage device comprising:
a memory device including a plurality of blocks, each block including memory cells; and
a controller configured to control the memory device to perform
a blind erase operation on a target block among the plurality of blocks, and
a fast erase operation on the target block in response to a determination that a new open block is required,
wherein, during the blind erase operation, the memory device performs an erase pulse applying operation on the target block without performing an erase verifying operation on the target block.

9. The storage device according to claim 8, wherein the controller is configured to control the memory device to perform the blind erase operation in response to a determination that the storage device is in an idle state.

10. The storage device according to claim 8, wherein the controller controls the memory device to perform the blind erase operation in response to a determination that no operation is pending for the memory device.

11. The storage device according to claim 8, wherein the controller is configured to enable a blind erase option in the memory device, and transmit an erase command set for the target block to the memory device to control the memory device to perform the blind erase operation.

12. The storage device according to claim 8, wherein the controller is configured to enable a pre-erase verifying option in the memory device, and transmit an erase command set for the target block to the memory device to control the memory device to perform the fast erase operation.

13. The storage device according to claim 12, wherein, during the fast erase operation, the memory device is configured not to perform an erase pulse applying operation on the target block before performing a pre-erase verifying operation on the target block.

14. The storage device according to claim 13,
wherein, during the fast erase operation, the memory device is configured to perform a normal erase operation on the target block in response to a determination that the pre-erase verifying operation fails, and
wherein, during the normal erase operation, one or more erase pulses are applied to the target block.

15. The storage device according to claim 8, wherein the controller is configured to select, from an invalid block pool, the target block on which the blind erase operation is to be performed.

16. The storage device according to claim 8, wherein the controller is configured to register, in a free block pool, the target block on which the blind erase operation is performed.

17. The storage device according to claim 16, wherein the controller is configured to select the target block from the free block pool in response to a determination that the new open block is required.

18. The storage device according to claim 8, wherein the controller is configured to determine whether the new open block is required, in response to a write request externally received.

19. The storage device according to claim 8, wherein the controller is configured to designate the target block as the new open block after the fast erase operation is performed, and control the memory device to perform a program operation on the target block.

20. An operating method of a storage device including a memory device and a controller, the operating method comprising:
controlling, by the controller, the memory device to perform a blind erase operation on a target block; and
controlling, by the controller, the memory device to perform a fast erase operation on the target block in response to a determination that a new open block is required.
